(19) United States
(12) Patent Application Publication
(10) Pub. No.: US 2023/0292620 A1
(43) Pub. Date: Sep. 14, 2023

(54) MANUFACTURING METHOD OF A STRAIN GAUGE SENSOR

(71) Applicant: Luxembourg Institute of Science and Technology (LIST), Esch/Alzette (LU)

(72) Inventors: Jérôme Polesel, Esch/Alzette (LU); Stephanie Girod, Esch/Alzette (LU); Raoul Joly, Esch/Alzette (LU); Patrick Grysan, Esch/Alzette (LU)

(21) Appl. No.: 18/040,041

(22) PCT Filed: Jul. 29, 2021
(86) PCT No.: PCT/EP2021/071307

§ 371 Date: Jan. 31, 2023

(30) Foreign Application Priority Data
Jul. 31, 2020 (LU) LU101963

(51) Int. Cl. H10N 30/30; G01L 1/16; H10N 30/076; H10N 30/06; H10N 30/093; H10N 30/87

(52) U.S. Cl. CPC H10N 30/302; G01L 1/16; H10N 30/076; H10N 30/06; H10N 30/093; H10N 30/877

(57) ABSTRACT

method of fabricating a sensor including a polymer body and a strain gauge including at least one Schottky junction. The Schottky junction includes an active layer including a piezoelectric semiconductor material, preferably with a wurtzite crystalline structure. The Schottky junction further including at least one metal electrode electrically connected to the active layer. The method including the following steps: forming a polymer layer, growing the at least one metal electrode on the polymer layer, then growing the active layer by atomic layer deposition, ALD, on the polymer layer and on the metal electrode. A sensor includes a polymer body and a cantilever including a strain gauge obtained by ALD. A gauge factor of 150 is achieved at different frequencies.

### TECHNICAL FIELD

The invention lies in the field of sensor manufacturing processes. More precisely the invention provides a fabricating process of a strain gauge with a Schottky feature. The invention also provides a sensor with a polymer body housing a strain gauge. The invention also provides a use of zinc oxide.

### BACKGROUND OF THE INVENTION

Chip sensors including cantilevers are commonly equipped with strain gauges at the clamped ends of the cantilevers. The lower faces of the cantilevers exhibit sensing tips which are useful for atomic force microscopy, AFM. The cantilever oscillations communicated by the protruding tips deform the strain gauges; thereby providing depth information of the probed surface.

However, such sensors generally offer a limited accuracy. The power consumption is important when monitoring a device with thousands of sensors. In the context of an energy autonomous devices, the service life is limited. Moreover, in known solutions, the gauge factors related to the strain detection sensitivity are not satisfying. Known manufacturing processes generally involve defects.

### TECHNICAL PROBLEM TO BE SOLVED

It is an objective of the invention to present a fabricating method, which overcomes at least some of the disadvantages of the prior art. In particular, it is an objective of the invention to present a reliable method of fabricating a sensor with a strain gauge.

### SUMMARY OF THE INVENTION

According to a first aspect of the invention it is provided a method of fabricating a sensor, said sensor comprising: a polymer body and a strain gauge including at least one Schottky junction, the Schottky junction comprising an active layer including a piezoelectric semiconductor material, preferably with a wurtzite crystalline structure, the Schottky junction further comprising at least one metal electrode electrically connected to the active layer; the method comprising the following steps: forming a polymer layer, growing the at least one metal electrode on the polymer layer, growing the active layer by atomic layer deposition (ALD) on the polymer layer.

Preferably, the step of growing the active layer may comprise using a deposition temperature ranging from: 20° C. to 150° C., preferably 60° C. to 100° C., more preferably 60° C. to 80° C.

Preferably, the active layer may comprise zinc oxide, ZnO, optionally magnesium doped zinc oxide, MgZnO, the active layer and the at least one metal electrode defining a Schottky barrier.

Preferably, the step of growing the active layer may comprise a sub step of molecular oxygen gas pulsing.

Preferably, the sub step of molecular oxygen gas pulsing may comprise a time length ranging from 1 second to 5 seconds. Preferably, said pulsing may be performed during a timespan lasting 1 to 5 seconds.

Preferably, the active layer may comprise at least one of the following materials: gallium nitride, GaN; cadmium sulphide, CdS; indium nitride, InN, scandium doped aluminium nitride, Sc-AlN and combinations thereof.

Preferably, the, or at least one, or each metal electrode may be a platinum electrode or may comprise a platinum alloy.

Preferably, the at least one metal electrode may be a gold electrode, or a silver electrode, or a palladium electrode; or the metal electrode may comprise: platinum alloy, or gold alloy, or silver alloy, or palladium alloy.

Preferably, the active layer may comprise a thickness ranging from 50 nanometres to 500 nanometres.

Preferably, the at least one metal electrode may comprise a thickness ranging from 100 nm to 200 nm.

Preferably, the at least one metal electrode may comprise a work function of: at least 5.0 eV; preferably 5.2 eV; more preferably 5.5 eV.

Preferably, at the step of growing the active layer, the active layer may grow on the metal electrodes.

Preferably, the at least one metal electrode may comprise two metal electrodes defining an interdigitated electrode, IDE, pattern.

Preferably, the active layer may include a wurtzite polycrystalline structure comprising a majority of grains exhibiting a (002) crystalline orientation, or a (001) crystalline orientation, or a (101) crystalline orientation.

Preferably, said (002) crystalline orientation, or (001) crystalline orientation, or (101) crystalline orientation may be perpendicular to the polymer layer.

Preferably, the active layer may comprise columnar (002) crystallite structures which are perpendicular to the polymer layer.

Preferably, the polymer layer may preferably be a transparent polymer layer, preferably the polymer body may be a transparent polymer body.

Preferably, the step of forming the polymer layer may comprise using a SU8 epoxy-based photoresist.

Preferably, the step of forming the polymer layer may comprise forming a polymer sensing peak, and/or at the step of growing the active layer, said active layer may grow above, or on top of, the sensing peak.

Preferably, the process may comprise a step of providing a sacrificial layer; at the step of forming the polymer layer, said polymer layer may be formed on said sacrificial layer; the process may further comprise a step of releasing, wherein the sensor is released from the sacrificial layer.

Preferably, the polymer body may comprise at least one cantilever, the at least one Schottky junction being in the cantilever, wherein the process may comprises a step of forming the at least one cantilever including a first sub step of forming a lower polymer film with a thickness equal to the addition of the thickness of the active layer plus the thickness of the polymer layer; and a second sub step forming an upper polymer film on the lower polymer film and on the active layer.

The Schottky junction may be comprised in a member or arm extending from the polymer body.

The member or arm may preferably be integrally formed with the polymer body.

Preferably, at the step of growing the metal electrode, said metal electrode may be grown by electron beam evaporation or by PVD sputtering.

Preferably, the step of growing the metal electrode may comprise a sub step of photoresist patterning by laser lithography with a defocussing, optionally a negative defocussing of at least −12.

Preferably, the at least one metal electrode may comprise two metal electrodes in electric contact with the active layer, preferably in order to form two back-to-back Schottky diodes.

Preferably, the active layer may define two Schottky junctions with the two metal electrodes.

Preferably, the active layer may form a separation interface, notably at least one Schottky interface, between the two metal electrodes with a width of at most 5 μm.

Preferably, the Schottky junction may be configured for forming a rectifying Schottky barrier.

Preferably, the Schottky junction may be at least partially in the cantilever, member, or arm.

Preferably, the or each cantilever may comprise a free, or distal end and a connection, or proximal end, such as a clamped end, at the body and opposite to the free end, the strain gauge being at the connection end.

Preferably, the step of growing the active layer may comprise the use of a temperature ranging from: 50° C. to 110° C., preferably 55° C. to 85° C.

Preferably, the active layer, optionally the wurtzite crystalline structure may comprise ceramic, preferably a piezoelectric semiconductor ceramic.

Preferably, the interdigitated electrode, IDE, pattern may comprise at least one set, preferably at least two sets, of parallel fingers.

Preferably, the first polymer layer processed may comprise a thickness ranging from 200 nm to 1 micrometer.

Preferably, the step of growing the active layer may comprise a sub step forming a passivation layer.

Preferably, at the step of forming the polymer layer, said polymer layer may form an edge with an edge height, at the step of growing the metal electrode, said metal electrode may exhibit a metal continuity along the edge height.

Preferably, at the step of forming the polymer layer, said polymer layer may form a chamfer; at the step of growing the metal electrode, said metal electrode may cover the chamfer.

Preferably, within the cantilever, the active layer may cover the majority of the surface; or substantially the whole surface; of the at least one metal electrode.

Preferably, the Schottky junction may comprise a contact interface between the active layer and the at least one metal electrode.

Preferably, the active layer may be thicker than the at least one metal electrode, preferably at least three times thicker.

Preferably, the ratio of the active layer thickness divided by the metal electrode thickness may range from 1 to 4.

Preferably, the active layer may comprise a width of at most: 100 μm, preferably 80 μm.

Preferably, the active layer may comprise a length of at most: 500 μm, preferably 310 μm.

Preferably, the or each cantilever may comprise a width of at most: 200 μm, preferably 120 μm.

Preferably, the or each cantilever may comprise a length of at most: 500 μm, preferably 200 μm.

Preferably, the at least one metal electrode may form an electrode layer vertically level with the active layer.

Preferably, the body may comprise an outer surface, the polymer layer may form a separation between the outer surface and the active layer and/or the at least one metal electrode.

Preferably, the strain gauge may be a first strain gauge, the sensor may further comprise a second strain gauge similar or identical to the first strain gauge.

Preferably, the polymer layer may partially form the polymer body, preferably the cantilever.

Preferably, each Schottky junction may define a Schottky barrier.

Preferably, the step of growing the active layer may be executed after the step of growing the at least one metal electrode.

Preferably, the active layer may comprise piezotronics material.

It is another aspect of the invention to provide a sensor comprising a polymer body including a strain gauge with at least one Schottky junction embedded in the polymer body; the Schottky junction comprising an active layer including a piezoelectric semiconductor material, said piezoelectric semiconductor material preferably comprising a wurtzite crystalline structure, at least one metal electrode electrically connected to the active layer, the active layer being obtained by atomic layer deposition, ALD, the polymer layer comprising a surface supporting the active layer and the at least one metal electrode, the sensor preferably being obtained by the method in accordance with the invention.

Preferably, the at least one metal electrode may be between the at least one metal electrode and the active layer.

The feature ALD is not an essential aspect of the invention.

It is another aspect of the invention to provide a sensor comprising a polymer body optionally including at least one cantilever, and a strain gauge with at least one Schottky junction in the polymer body, the Schottky junction comprising an active layer, or active film, including a semiconducting piezoelectric material, preferentially with a wurtzite crystalline structure; and at least one metal electrode comprising a work function of at least: 5.00 eV; or 5.20 eV; or 5.50 eV.

It is another aspect of the invention to provide a sensor comprising a polymer main portion, notably a main body, a polymer portion of reduced thickness, notably a cantilever, arm or member, and a strain gauge with at least one Schottky junction optionally at the optional portion of reduced thickness, the Schottky junction comprising an active layer including a semiconducting piezoelectric material; preferentially with a wurtzite crystalline structure, and at least one metal electrode electrically connected to the active layer; the active layer and the at least one metal electrode preferably forming a Schottky diode and/or a Schottky contact, and/or a Schottky barrier, or a Schottky feature.

It is another aspect of the invention to provide a sensor comprising a polymer body optionally including at least one cantilever, arm or member, and a strain gauge with at least one Schottky junctions; the Schottky junction(s) comprising at least one metal electrode, and an active layer which defines a Schottky contact with the metal electrode, which includes material, preferentially with a wurtzite crystalline structure; and which comprises a thickness ranging from 50 nm to 500 nm, preferably from 100 nm to 400 nm.

It is another aspect of the invention to provide a sensor comprising a polymer body, such as a chip body, optionally a polymer cantilever protruding from the polymer body, notably a polymer arm; and a strain gauge which includes an active layer including a piezoelectric semiconductor material; preferentially with a wurtzite crystalline structure; and at least one metal electrode electrically connected to the active layer in order to define one or a plurality of Schottky junction in the polymer cantilever.

Preferably, the active layer may be formed by physical vapor deposition, PVD.

It is another aspect of the invention to provide a strain gauge including a contact interface formed by platinum electrode and a zinc oxide layer, optionally on a polymer layer.

It is another aspect of the invention to provide a use of zinc oxide, ZnO comprising a main (002) crystalline orientation for forming an active layer of a Schottky junction of a strain gauge on a polymer layer perpendicular to the main (002) crystalline orientation.

It is another aspect of the invention to provide a use of a zinc oxide, ZnO, for forming an active layer of a Schottky junction, preferably a Schottky diode, more preferably a Schottky barrier; of a strain gauge, the active layer comprising columnar (002) crystallite structures which are perpendicular to the strain gauge; the active layer comprising a first face perpendicular to the (002) axis of the (002) crystallite structures, the strain gauge further comprising two electrodes, preferably interdigitated electrodes, IDE, which are arranged at said first face.

It is another aspect of the invention to provide a use of an active layer comprising a wurtzite structure for forming a Schottky barrier in a strain gauge, optionally with at least one metal electrode comprising a work function of at least: 5.00 eV; or 5.20 eV; or 5.50 eV.

It is another aspect of the invention to provide a measuring process with a sensor in accordance with the invention, the process comprising the steps of providing a sample, deforming the strain gauge;
and measuring data relating to the sample with the sensor.

Preferably, the measuring process may be a strain sensing process or a stress sensing process.

Preferably, the measuring process may be integrated in an atomic force microscopy (AFM) process and/or system.

Preferably, during the step of measuring, a bias voltage of at least 10V may be applied to the at least one metal electrode.

Preferably, during measuring, the strain gauge may comprise a power consumption of at most 50 μW.

Preferably, the cantilever may be a transparent cantilever, the process may further comprise a step of acquiring image data of the sample through the transparent cantilever.

The different aspects of the invention may be combined with each other. In addition, the preferable features of each aspect of the invention may be combined with the other aspects of the invention, unless the contrary is explicitly mentioned.

### TECHNICAL ADVANTAGES OF THE INVENTION

The invention improves the behaviour of the Schottky junction of a strain gauge for a sensor.

The gauge factor is improved. The power consumption is reduced.

### BRIEF DESCRIPTION OF THE DRAWINGS

Several embodiments of the present invention are illustrated by way of figures, which do not limit the scope of the invention, wherein

FIG. 1 provides a side view of a sensor in accordance with a preferred embodiment of the invention;

FIG. 2 provides a top view of a sensor in accordance with a preferred embodiment of the invention;

FIG. 3 provides a schematic illustration of interdigitated electrodes (IDE) forming one or two Schottky interface(s) of a sensor in accordance with a preferred embodiment of the invention;

FIG. 4 provides a through cut of one or two Schottky diodes of a sensor in accordance with a preferred embodiment of the invention;

FIG. 5 provides an illustration of the bands structure with a Schottky barrier Φ_{B} of a sensor in accordance with a preferred embodiment of the invention;

FIG. 6 provides a diagram block of a measuring process in accordance with a preferred embodiment of the invention;

FIG. 7 provides a diagram block of a method for fabricating a sensor in accordance with a preferred embodiment of the invention;

FIG. 8 provides a detailed diagram block of a method for fabricating a sensor in accordance with a preferred embodiment of the invention;

FIG. 9A, FIG. 9B and FIG. 9C provide Scanning Electron Microscopy (SEM) top view images of zinc oxide layers deposited by Atomic Layer Deposition (ALD) at different temperature for a sensor, and/or a method in accordance with a preferred embodiment of the invention;

FIG. 10 provides diffraction patterns of ZnO films grown at different temperature for a sensor, and/or a method in accordance with a preferred embodiment of the invention;

FIG. 11 provides a XPS survey spectrum of a ZnO thin film deposited by ALD for a sensor, and/or a method in accordance with a preferred embodiment of the invention;

FIG. 12 provides a graph illustrating the evolution of the O:Zn atomic ratio depending on growing temperature for a sensor, and/or a method in accordance with a preferred embodiment of the invention;

FIG. 13 provides a graph illustrating the resistance of ZnO thin films grown by ALD for different deposition temperatures for a sensor in accordance with a preferred embodiment of the invention;

FIG. 14 provides a graph illustrating the gauge factor for a sensor at different bias voltages and different signal frequencies of the input bias in accordance with a preferred embodiment of the invention;

FIG. 15 provides a graph illustrating the transducing response of the piezotronic strain microsensor by the mean of I(V) current-to-bias voltage curves in accordance with a preferred embodiment of the invention.

### DETAILED DESCRIPTION OF THE INVENTION

This section describes the invention in further detail based on preferred embodiments and on the figures. Similar reference numbers will be used to describe similar or the same concepts throughout different embodiments of the invention.

It should be noted that features described for a specific embodiment described herein may be combined with the features of other embodiments unless the contrary is explicitly mentioned. Features commonly known in the art will not be explicitly mentioned for the sake of focusing on the features that are specific to the invention. For example, the sensor in accordance with the invention is evidently powered by an electric supply, even though such supply is not explicitly referenced on the figures nor referenced in the description.

In the current description, a layer may be understood as a level or a stratum, for instance within the sensor.

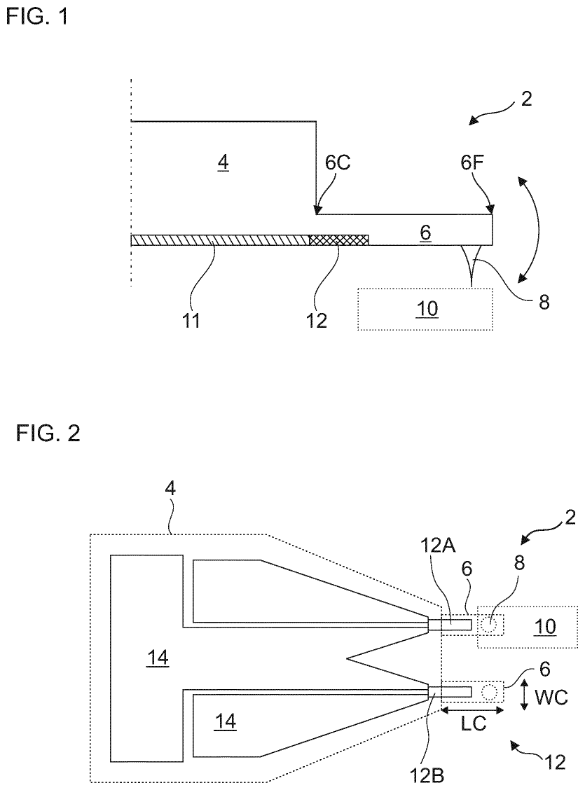

FIG. 1 shows a sensor 2 in accordance with a preferred embodiment of the invention.

The sensor 2 comprises a chip body 4 (partially represented) with at least one cantilever 6 projecting from the chip body 4. The cantilever 6 forms an arm or member protruding from the body. It is thinner than the chip body 4, thus it is more resilient. The cantilever 6 comprises a free or distal end 6F at the opposite from the chip body 4, and a connection or proximal end; also designated as clamped end 6C. The clamped end 6C is at the interface with the chip body 4. An optional tip 8 projects from the lower face of the cantilever 6. The tip 8, also designated as sensing peak 8 or needle, is adapted for sensing a provided sample 10 (represented with a dotted line) that is under investigation. The body 4 may comprise a polymer, such as a SU8 polymer. The body 4, the cantilever 6 and the tip 8 are preferably integrally formed as a single piece, and made of SU8 epoxy. Transparent polymer may be used. Thus, it becomes possible to acquire image data of the sample through the cantilever 6.

The sensor 2 includes at least one contact electrode 11 associated with one strain gauge 12. The strain gauge 12 extends at least partially in the cantilever, member or arm 6. During measuring operations, the cantilever 6 oscillates, thereby deforming the strain gauge 12. The electrical properties of the strain gauge 12 varies upon deformations, thereby allowing to observe the probed surface, for instance in accordance with the atomic force microscopy, AFM.

By way of illustration, the sensor 2 includes two cantilevers 6, preferably similar or identical cantilevers 6. Each cantilever comprises a strain gauge 12 electrically connected to an associated contact electrode 11.

FIG. 2 shows a planar view of a sensor 2 in accordance with a preferred embodiment of the invention. The sensor 2 may be similar or identical to the one as described in relation with FIG. 1. The sensor 2 includes a main body 4, two cantilevers 6, and a sensing peak 8 at one of the cantilevers 6. The sensing peak 8 may be at distance, notably longitudinally, from the associated strain gauge 12A. Each cantilever 6 is associated with a strain gauge 12. Preferably each cantilever 6 is associated with a distinct strain gauge 12. The strain gauges comprise a sensing strain gauge 12A, illustrated in the top portion of FIG. 2; and a reference strain gauge 12B, illustrated in the bottom portion of the figure, without limiting the invention to this specific arrangement.

Due to the pair of strain gauges 12A, 12B, differential measuring is enabled. One of the cantilevers 6 cooperates with the sample 10, and the other of the two cantilevers is at distance of the sample 10. Then the sensing strain gauge 12A provides sensing data, and the reference strain gauge 12B provides data relating to sensing conditions. Noise and drift data may be deduced, thereby improving the accuracy and the signal-to-noise ratio, SNR, of the obtained properties.

The strain gauges 12 comprise electrodes 14, notably metal electrodes 14. One of the electrodes 14 may connect both strain gauges 12. Each strain gauge 12 may comprise a sensing portion, or active area, extending in the associated cantilever 6.

The cantilevers 6 may be microscale cantilevers 6. Each cantilever 6 may comprise a length LC of at most: 500 μm, preferably 200 μm. Each cantilever 6 may comprise a width CW of at most: 200 μm, preferably 120 μm.

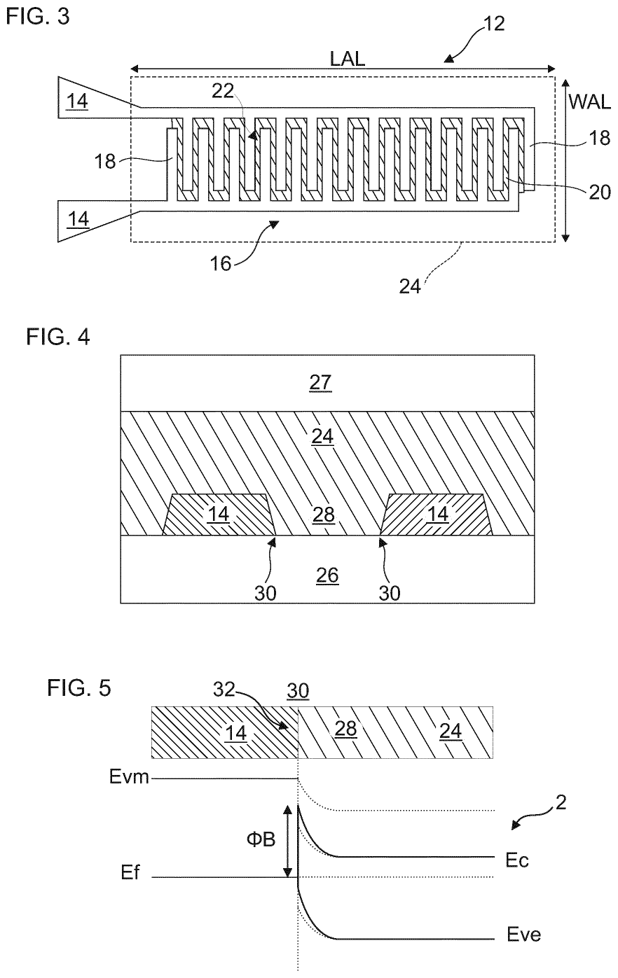

FIG. 3 provides a schematic illustration of a strain gauge 12 for a sensor in accordance with a preferred embodiment of the invention. The sensor may be similar or identical to those as described in relation with FIG. 1 and/or 2. The body and the cantilever are omitted for the sake of clarity. The metal electrodes 14 define an interdigitated electrode, IDE, pattern 16. Each metal electrode 14 comprises a set of parallel fingers 18 which extend between the fingers 18 of the set of the other metal electrode 14. This arrangement allows to set an equivalent model of several back-to-back Schottky junctions in parallel, and not only one. This improves the strain sensitivity of the sensors by summing many back-to-back Schottky diode currents impacted by the same mechanical strain signal. By way of illustration only, and without limiting the invention to this number of fingers, each set comprises sixteen fingers 18. The finger sets are intermingled and form an interleaving pattern. The sets extend within each other. The fingers 18 form strips of metal, or metal tracks. The electrodes 14 may form combs. The metal electrodes 14 are separated. A separation 20 extends between the fingers. The separation 20 forms a serpentine. The separation 20 forms an interface 22 between the adjacent fingers 18. The separation 20 may present a width of at most 5 μm, measured between adjacent fingers 18.

The metal electrodes 14 may define a metal layer. The metal electrodes 14 may comprise a high work function metal, such as platinum, Pt, or platinum alloy. At least one or each metal electrode 14 may comprise a work function of at least: 5.00 eV; or 5.20 eV; or 5.50 eV, or 5.70 eV. As an alternative or in addition, the metal electrodes 14 may comprise gold, or silver, or palladium, or their alloys. The metal electrodes 14 may comprise different materials or alloys. A first electrode may comprise a first metal, and a second electrode may comprise a second metal. The first and second electrodes may comprise different metals selected from the above list of materials.

The strain gauge 12 may comprise an active layer 24. The active layer 24 may fill the separation 20. It may fill the interface 22. The active layer 24 may cover the metal electrodes 14. It may form a coating thereon. The active layer 24 may span beyond the electrodes 14. The active layer may be thicker than the electrodes 14. The metal electrodes 14 may be embedded in the active layer 24. Hence, the active layer 24 is enclosed in the corresponding cantilever, and in the body. It may be observed through the transparent polymer.

By way of illustration, the active layer 24 comprises a width WAL of at most: 100 μm, preferably 80 μm. The active layer 24 may comprise a length LAL of at most: 500 μm, preferably 310 μm. When the strain sensor 12 is bent, the active layer 24 is stressed between the fingers 18. It may experience a compression stress or a tensile stress depending on the curvature of the cantilever. The active layer 24 comprises piezoelectric material. The piezoelectric material is preferably a piezoelectric semiconductor. The active layer 24 may comprises a ceramic material. The active layer 24 may comprise a hexagonal crystalline structure, such as a wurtzite crystalline structure. The active layer 24 may comprises zinc oxide, ZnO, for instance magnesium doped zinc oxide, MgZnO. The active layer 24 may comprise zinc oxide, ZnO, with a (002) wurtzite crystalline structure.

As an alternative, the active layer 24 comprises at least one of the following materials: gallium nitride, GaN; cadmium sulphide, CdS; indium nitride, InN; scandium doped aluminium nitride, Sc-AlN; and combinations thereof.

More generally, the active layer may comprise a piezotronic material.

The active layer 24 may be formed by atomic layer deposition, ALD, on a polymer layer forming the body at least partially. The atomic layer deposition, ALD, technique improves uniformity of the active layer 24. It also preserves the polymer layer receiving the active layer 24 and the metal electrodes 14. The ALD feature may be detected by microscopy.

The metal electrodes 14 and the active layer 24 define Schottky interfaces. The Schottky interfaces may extend along the interface 22 between the interdigitated fingers 18. More generally, they defined a Schottky feature.

FIG. 4 shows two metal electrodes 14 potted, or included, in the active layer 24 for a sensor in accordance with a preferred embodiment of the invention. The sensor may be similar or identical to those as described in relation with any of FIGS. 1 to 3, and combinations thereof.

The metal electrodes 14 and the active layer 24 are supported by a polymer layer 26, notably a lower layer 26 or first polymer layer. In addition, a top layer 27 is provided on the active layer 24. The top layer 27 may be a second polymer layer 27 covering the active layer. The top polymer layer 27 may be a protective layer, also designated as passivation layer. The active layer 24 may be encapsulated between the layers 26 and 27. The active layer 24 covers the metal electrodes 14 which are interlocked, nested therein. As an option, they respectively comprise platinum, Pt, and zinc oxide, ZnO.

The two metal electrodes 14 and the portion of active layer 24 therebetween define at least one Schottky diode 28, notably two back-to-back Schottky diodes 28. Each of the two Schottky junctions 30 is associated with one of the two metal electrodes 14. The junctions 30 may be formed by inclined edges of the metal electrodes 14. Thus, the material continuity is improved.

The active layer 24 is thicker than the metal electrodes 14. The metal electrodes 14 are at least two times thinner than the active layer 24, preferably at least three times thinner than the active layer 24. The active layer 24 may comprises a thickness ranging from: 50 nanometres (nm) to 500 nanometres, preferably from 200 nm to 400 nm. The active layer 24 may comprise a thickness of 300 nm. The metal electrodes 14 comprise a thickness ranging from 100 nm to 200 nm.

As an alternative, the active layer is thinner than the electrode layer. Then, the electrodes are higher than the active layer. The active layer overhangs the electrodes.

FIG. 5 shows a Schottky junction 30 for a sensor in accordance with a preferred embodiment of the invention. The band structure diagram is represented in superposition below. The sensor may be similar or identical to those described in relation with any of FIGS. 1 to 4, and combinations thereof.

The sensor 2 exhibits a metal electrode 14 adjacent to an active layer 24. The active layer 24 and the metal electrode 14 are physically in contact. They form a Schottky contact at the Schottky junction 30 apparent at one end of the Schottky diode 28.

The Schottky junction 30 is configured for forming an obvious Schottky barrier OB 32, preferably a rectifying Schottky barrier. This result is obtained by the use of a high work function metal in the electrode 14, and of the piezoelectric semiconductor. The combination of platinum and zinc oxide provides an interesting contact interface for a strain gauge.

The band diagram may correspond to a n-type semiconductor Schottky barrier Φ_{B} 32. The parameters Evm, Ef, EC, and Eve respectively correspond to: the Vacuum level, the Fermi level of the metal electrode 14, the conduction band of the piezoelectric semiconductor material of the active layer 24, and the valence band of the semiconductor.

The current density JnO flowing through a metal/semiconductor junction under a forward bias V can be written as:

Jn0=A*·T²·exp({−q·ϕB0}/{kB·T})·[exp({q·[V−I·RS]}/{η·kB·T})−1]

Where Jn0 and ϕB0 are respectively the current density and the Schottky barrier height in the absence of piezoelectric polarization charges, A* the Richardson constant, q the elementary charge, T the temperature, kB the Boltzmann constant, RS the series resistance of the semiconductor and η the ideal factor of the diode. The term “exp” corresponds to exponential function. Under straining, the created piezo-charges density ρpiezo at the metal/semiconductor interface not only change the height of the Schottky barrier height ϕB0, but also its width by Wpiezo, as: ϕB=ϕB0−{(q²·ρpiezo·Wpiezo²)/(2·εS)}, with εS the dielectric constant of the semiconductor.

Thus, the current density Jn flowing through the junction in the presence of piezoelectric polarization charges can be written as:

Jn=A*·T²·exp({−q·ϕB0}/{kB·T})·exp({q²·ρpiezo·Wpiezo²}/{2·εS·kB·T})·[exp({q·(V−I·RS)}/{η·kB·T})−1]

This means that the current transported across the metal/semiconductor contact is an exponential function of the local piezo-charges, the sign of which depends on the strain ε, with:

P=d·σ=d·E·ε=q·ρpiezo·Wpiezo

Where P is the piezoelectric polarization, d the piezoelectric coefficient of the semiconductor, σ the stress, E the Young Modulus of the semiconductor.

This finally results in the following equation:

Jn=A*·T²·exp({−q·ϕB0}/{kB·T})·exp({q·Wpiezo·d·E·ε}/{2·εS·kB·T})·[exp({q·(V−I·RS)}/{η·kB·T})−1]

Therefore, the current transported through the metal-semiconductor junction can be effectively tuned or controlled not only by the magnitude of the strain, but also by the sign of the strain (tensile vs. compressive). This is the rationale of the piezotronic junction. The main studied piezotronic material systems for mechanical strain sensing consists of zinc oxide, ZnO, semiconductor.

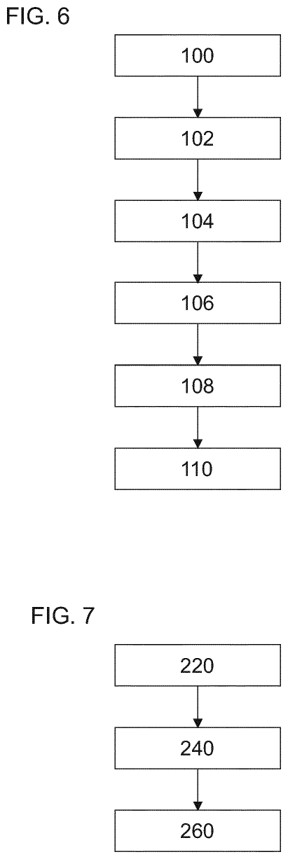

FIG. 6 shows a block diagram illustrating the main steps of a measuring process with a sensor in accordance with embodiments of the invention. The sensor may be similar or identical to those described in relation with any of FIGS. 1 to 5, and combinations thereof.

The measuring process comprises the following steps:
providing 100 a sample with a surface,
deforming 102 the strain gauge;
measuring 104 data about the sample surface probed by the sensor, notably by differential measurement between the sensor data probe 12A and the reference one 12B as defined in relation with FIG. 2;
acquiring 106 image data of the sample surface probed by means of vision means such as a camera;
computing 108 data from the sensor using data processing means, for example comprising a data processor;
storing 110 data from the sensor in a memory element.

Steps 106 to 110 are purely optional in the scope of the current invention.

At step measuring 104, a 10 V bias potential is applied between the electrodes.

As an option or an alternative, the measuring process is a strain sensing process or a stress sensing process. Further, the measuring process may be integrated in an atomic force microscopy, AFM, process with controlled lateral scanning in X and Y of either the strain sensor or the sample surface.

During measuring 104, the strain gauge may comprise a power consumption of at most 50 μW.

At step acquiring 110, the image data comprises images of the sample surface probed through the transparent cantilever.

FIG. 7 shows a block diagram illustrating the main steps of a method of fabricating a sensor in accordance with embodiments the invention. The sensor may be similar or identical to those described in relation with any of FIGS. 1 to 5, and combinations thereof.

The process comprises the following steps, notably executed as follows:
forming 220 a polymer layer,
growing 240 the at least one metal electrode on the polymer layer,
growing 260 the active layer by atomic layer deposition, ALD, on the polymer layer.

The atomic layer deposition, ALD, provides a thin active layer. In addition, the active layer is homogeneous. The Schottky behaviour of the junction is well respected.

The current method of fabricating the sensor may be a method a fabricating a strain gauge.

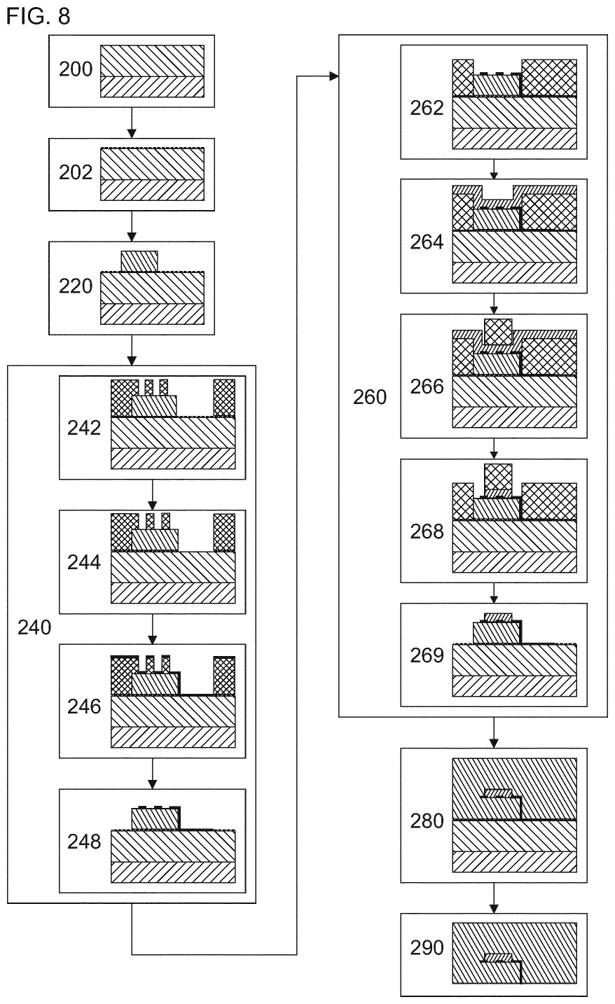

FIG. 8 shows a block diagram illustrating the main steps of a method of fabricating a sensor in accordance with embodiments of the invention. The sensor may be similar or identical to those described in relation with any of FIGS. 1 to 5, and combinations thereof The method may be similar to the method as detailed in relation with FIG. 7.

The process comprises the following steps, notably executed as follows:
providing 200 a substrate;
oxidation 202 of the substrate;
forming 220 a polymer layer, notably on the substrate;
growing 240 the at least one metal electrode on the polymer layer;
growing 260 the active layer by atomic layer deposition (ALD) on the polymer layer;
forming 280 the at least one cantilever, preferably at least two cantilevers;
releasing 290 the sensor from the substrate.

At the step of providing 200 a substrate, the substrate may be a sacrificial substrate also designated as sacrificial layer. The full sensor structure may be built on a silicon wafer of at least 2 inches diameter and then released via the etching of a sacrificial layer. The sacrificial layer may comprise a 2 μm thick sputtered copper layer with a 10 nm thick titanium adhesion layer.

The chosen material has to be easy to etch for the structures releasing step but inert to the chemicals involved during the different fabrication steps. It also has to present an adhesion threshold with respect the other materials involved like platinum and SU8 photoresist. Different materials and thicknesses are considered such as gold, aluminium and copper. The lithography developer based on TetraMethylAmmonium Hydroxide, TMAH, etches aluminium. Thick SU8 layers have a very poor adhesion to gold, leading to a delamination during SU8 200 μm development. Finally, a sacrificial layer of copper 2 μm has been found as the best compromise. As an alternative or as an option, the substrate may be provided with a sensing peak.

As a first alternative step in the modified process, a silicon wafer 100 is selectively etched by KOH to obtain pyramidal hollows with 111 sides as is well known to those skilled in the art. Then the sacrificial layer made of a 2 μm thick sputtered copper with a 10 nm thick titanium adhesion layer as defined in step 200.

As an second alternative step, a copper oxidation is executed as in step 202, with the benefit of an oxidation sharpening improving the top SU8 tip apex.

Then, the next alternative steps are performed to shape the SU8 tip by a SU8 3005 or SU8 3010 spin coating followed by the standard steps (pre-bake→UV exposure→postbake→development) of patterning as is well known to those skilled in the art. Hence, only the tip patterned area remains on the surface. Depending of the SU8 thickness of the remaining mesa on the surface, advantageously a post-processing by Reactive Ion Etching, RIE, can be added with a pressure of 80 milliTorr with a gas mix of O2:CF₄ (95:5 ratio), power of 100 Watts to etch during 10 seconds to 5 minutes the upper part of the SU8 mesa. Hence an embedded SU8 tip in the surface is obtained. The next third alternative step comprises the deposition of the SU8 encapsulation layer as described in the method described in relation with FIG. 8 at the step 220 of forming a polymer layer.

At the step of oxidation 202, the surface of the sacrificial layer is oxidized on a hotplate at 200° C. for 40 seconds. The stack comprising the SU8 10 μm and SU8 200 μm tends to delaminate from the copper sacrificial layer during the long immersion in SU8 developer, within the development step of SU8 200 μm. The adhesion of SU8 to copper can be increased by a soft oxidation of copper surface

The benefit for improvement of SU8 adhesion to Cu via its oxidation is associated to a deficit with a poor adhesion of Pt on Cu oxide. The issue is solved by an etching of copper oxide with acetic acid 10% for 1 min just before Pt evaporation. The duration of copper oxidation in step 2 is fixed to 40 seconds to limit the oxide thickness to the minimum and then the increase of step height between SU8 300 nm encapsulation layer and sacrificial layer. A step that is too high or too important can lead to a non-continuity of Pt contact.

At the step 220 of forming a polymer layer, a first SU8 300 nm thin layer that will act as ZnO passivation layer is patterned. SU8 2000.5 Photoresist is spin coated at a speed of 10000 rpms, with an acceleration of 4000 rpms/s for 30 s, leading to a 390 nm thick layer. The resist is then pre-baked on a hotplate from 50° C. to 95° C. with a 350° C./h ramping. It is left at 95° C. for 1 minute before being removed from the hotplate. Exposure is performed by direct laser lithography (Heidelberg MLA 150™, laser wavelength λ=375 nm) with a dose of 2800 mJ/cm² and light defocusing of −12. A post exposure bake is performed from 50° C. to 95° C. (350° C./h ramping) and left at 95° C. for 1 minute before being removed from the hotplate. Development is done in SU8 developer for 10 seconds before a rinse in isopropanol for 30 seconds. A final hardbake is performed on a hotplate at 150° C. for 15 minutes. A last plasma etching step (Ar:O2) is used to reduce the thickness to 300 nm.

The illustrated step 240 of growing the metal electrode comprises a sub step of photoresist patterning 242 by laser lithography with defocussing. The defocussing is preferably a negative defocussing. The defocussing allows the formation of inclined edges on the metal electrodes. The electrodes may exhibit a trapezoidal cross section. Thus, it is easier to provide electric continuity. By way of illustration, the negative defocussing is of at least: −8, or −10, or −12, or −15.

Pt electrodes, or electrodes of other metals, are patterned by photoresist spin coating, direct laser writing photolithography, metal deposition and lift-off process. A bilayer of photosensitive resists is spincoated on the substrate. The first photoresist layer is a 350 nm thick layer of LOR 3A from MicroChem™. Spin coating is done at 6000 rpms with a 4000 rpms/s acceleration for 30 seconds. The prebake is performed on a hotplate at 115° C. for 5 minutes. The second photoresist layer is a 1.3 μm thick layer of Microposit S1813™. Spin coating is performed at 4000 rpms with a 6000 rpms/s acceleration for 60 seconds. The prebake is completed on a hotplate at 115° C. for 1 minute. Patterns are defined by direct laser writing photolithography (Heidelberg MLA150™, laser wavelength λ=375 nm), using a dose of 91 mJ/cm² and light defocusing of −3. Patterns are developed after exposure in Microposit MF319™ developer for 40 seconds and rinsed in deionized water for 60 seconds.

The step 240 of growing the metal electrode may comprise a sub step of etching 244. The sub step of etching 244 is intended to remove the oxidation layer formed during step oxidation 202 of the substrate. For instance, the sub step 244 of etching may remove a copper oxide film. By way of illustration, copper oxide is locally etched for 1 minute in acetic acid 10%.

The step 240 of growing the metal electrode may comprise a sub step of forming 246 or deposition of the metal electrode, notably each metal electrode. Layers of Ti5 nm /Pt100 nm are grown on top of the patterned photoresist, either by electron beam evaporation or by PVD sputtering. PVD sputtering, or Physical Vapor Deposition by sputtering is a well-known technique as such and will not be detailed further.

A highly critical point of the method is to keep the deposited platinum continuity between sensing interdigitated electrodes on SU8 encapsulation layer and large bounding pads on copper sacrificial layer. This is mandatory to maintain an electrical continuity of the stepped electrode. The difficulty arises from the 300 nm abrupt step at the SU8 encapsulation layer edge. The issue was solved by taking advantage of maskless aligner capabilities to shift the laser focalisation point by several microns from the resist surface. The laser defocalisation leads to less defined patterns edges. This diverted use of the MLA 150 laser lithography defocusing capabilities makes it possible to obtain resist edges with high positive slopes (trapezoidal shape), favouring platinum continuity.

The step 240 of growing the metal electrode may comprise a sub step lift-off 248 in order to remove the mask formed at the sub step photoresist patterning 242. In a non-limiting manner, step lift-off 248 is carried out by immersing the wafer in a bath of Remover PG solvent from MicroChem™ for 30 minutes. It is then rinsed with Remover PG, Acetone and Isopropanol.

The step 260 of growing the active layer comprises a sub step of forming 262 a passivation layer, for instance a passivation layer to avoid copper chemical etching during the next steps. The copper sacrificial layer is passivated with photoresist to prevent it to be etched during the etching of ZnO. A layer of S1813 is spincoated on the substrate and patterned by direct laser writing photolithography (Heidelberg MLA150™, laser wavelength λ=375 nm), using a dose of 100 mJ/cm². Patterns are developed after exposure in Microposit MF319™ developer for 60 seconds and rinsed in deionized water for 60 seconds.

The step 260 of growing the active layer may be a step of forming the active layer. The step 260 of growing the active layer may comprise a sub step of deposition 264 of the active layer. Soft oxygen/argon plasma pre-treatment is performed for 20 seconds to remove organic residues from the electrode surface. This step is used to ensure good ZnO/Pt and ZnO/SU8 interfaces quality, which are important to obtain proper Schottky interfaces. A 300 nm layer of ZnO is then grown by atomic layer deposition, ALD, on the whole substrate surface. Growing temperatures from 60° C. to 100° C. are used without fixing agent.

The ALD technique is based on surface reactions for the deposition of thin films onto a substrate, changing this substrate thus consists in a major challenge. An important technical requirement is related with the deposition temperature of the ALD process, in order to avoid the degradation of the substrate. Because the glass transition temperature of SU8 after cross-linking is located around 200° C., subsequent ALD processes should be performed below this temperature to prevent a reflow phenomenon. Additionally, prior to the deposition of ZnO, a plasma pre-treatment was applied to the SU8 surface, consisting in a soft oxygen/argon plasma. The aim of this pre-treatment is to increase its wettability by inducing surface oxidation. The low quantity of oxygen contained within the plasma has a meaningful etching effect and chemical top moieties change on the polymeric substrates.

The step 260 of growing the active layer, for instance during the sub step of deposition 264, comprises a sub step of molecular oxygen gas pulsing. The sub step of, or the process of, molecular oxygen gas pulsing comprises a time length ranging from 1 second to 5 seconds.

The piezoelectric semiconducting thin layer made by ALD represents an important stage to modulate the series resistance of the diode junction, but also the mobility and the density of the free carriers, as well as the resistivity inside the material by an interplay between the crystalline structure and the Zn:O stoichiometry.

For a given temperature of growth on top of the polymer surface, we introduced the use of molecular oxygen gas pulsing in the cycle of the ALD processing to control these electronic parameters.

In accordance with a preferred embodiment of the process, the deposition cycle comprises a diethylzinc, DEZ, pulse followed by a pulse of deionized water, while using argon as an inert purging gas. The variant of the process presented in this section includes in the introduction of a molecular oxygen gas pulse in between the DEZ and the deionized water pulses. The purging time of the molecular oxygen gas pulse is set to 20 s to avoid any potential parasitic CVD reaction inside the ALD reactor. Particular attention has been given to the purity of the molecular oxygen gas used. Alphagaz 2 Oxygen has been used with a global purity ≥99.9995% mol and H2O≥0.5 ppm.mol. The oxygen gas carrying line has been filtered with a cartridge to avoid any unwanted reaction between moisture contamination and DEZ.

The incorporation of molecular oxygen within the ALD process is leading to a preferred (002) crystalline orientation with fine columnar crystallites at a temperature of 100° C. and above. A transition is occurring below 100° C., where a different distribution of grain orientations can be observed, shared between the (100), (002) and (101) crystalline orientations. This is further confirmed by SEM top view images showing a distribution of wedge-like shaped crystallites parallel to the substrate and of fine columnar crystallites perpendicular to the substrate.

A substantial increase of the resistivity for the ZnO thin films deposited with oxygen gas can be noticed, which is attributed to the decrease in the concentration of oxygen vacancies. This is further confirmed by the O:Zn ratios of ZnO thin films deposited using oxygen gas which are superior to those of ZnO thin films without oxygen gas. This increase of the resistivity decreases advantageously the leakage currents by increasing the piezoelectric efficiency of this ceramic thin film.

Concerning piezoelectric-based applications as for piezotronic strain sensors, ZnO thin films are required to present a preferred (002) crystalline orientation together with a high resistivity—or low leakage current—to ensure the highest output voltages. This ALD process thus allows to tune the structural and electrical characteristics of the deposited ZnO thin films by incorporating molecular oxygen gas, with properties adapted for piezoelectric applications for temperatures above 100° C. ZnO deposited with oxygen gas has been found more sensitive to abrupt thermoplastic deformation. This phenomenon can be explained by its well-defined columnar crystallites structure perpendicular to the substrate. It is principally induced by the baking operations during the process, where materials with different thermal expansion coefficients are involved.

The step 260 of growing the active layer may comprise a sub step of forming 266 a mask on the active layer.

ZnO micropads are defined by chemical wet etching through a resist mask. The resist mask comprises a spincoated 1.3 μm S1813 photoresist layer, patterned by direct laser writing photolithography (Heidelberg MLA150™, laser wavelength λ=375 nm), using a dose of 100 mJ/cm². Patterns are developed after exposure in Microposit MF319™ developer for 60 seconds and rinsed in deionized water for 60 seconds.

The step 260 of growing the active layer comprises a sub step of etching 268 the active layer, for instance away from the mask on the active layer. The active layer is kept between, and possibly on the metal electrodes. Then, an active pad is provided in contact of the electrodes. The ZnO etching is performed with a FeCl₃:H₂O 740 mMol solution for 2 minutes. The etching mask is enlarged to compensate the 16 μm lateral isotropic etching.

The step 260 of growing the active layer comprises a sub step of removing 269 masks. The resist masks are removed after etching with acetone.

The step 280 of forming the at least one cantilever, member or arm may comprise a first sub step of forming a lower polymer film with a thickness equal to the addition of the thickness of the active layer plus the thickness of the polymer layer; and a second sub step of forming an upper polymer film on the lower polymer film and on the active layer. The second sub step of forming an upper polymer film, may be a step of capping the active layer. The top polymer layer is formed or grown on the active layer.

The cantilevers are patterned by direct laser writing photolithography from a 10 μm thick SU8 epoxy photoresist layer. SU8 3010 is spin coated in two consecutive steps. The first step consists in a 500 rpms speed with a 100 rpms/s acceleration for 5 seconds. The second step consists in a 2600 rpms speed with a 300 rpms/s acceleration for 30 s. The prebake is performed on a hotplate, ramped up from ambient temperature to 65° C., the wafer is left at 65° C. for 5 minutes. It is then ramped up to 95° C., left at 95° C. for 7 minutes and ramped down to ambient temperature. All the ramps used are set to 150° C./h. Exposure is performed by direct laser writing photolithography (Heidelberg MLA150™, laser wavelength λ=375 nm), using a dose of 1015 mJ/cm² and light defocusing of +3. A post exposure bake is performed in the same way as prebake, wafer is left at 65° C. for 2 minutes and 95° C. for 4 minutes. Patterns are developed using two baths of SU8 developer. Development is achieved after 2 minutes 15 seconds in the first bath, 15 seconds in the second bath and 15 seconds of rinsing in isopropanol. SU8 is finally baked on hotplate at 150° C. for 45 minutes to complete crosslinking and release strain.

During or after step 280 of forming the at least one cantilever, the process may comprise a step (not represented) of forming the polymer body, also designated as chip body.

The chip body may also be patterned by direct laser writing photolithography from an SU8 epoxy photoresist layer. The SU8 used for this step is 200 μm thick. SU8 100 is spincoated in two consecutive steps. The first step consists in a 500 rpms speed with a 100 rpms/s acceleration for 10 seconds. The second step consists in a 1250 rpms speed with a 300 rpms/s acceleration for 80 s. The wafer is left at ambient conditions for 12 hours to allow the flattening of the resist. Prebake is performed on a hotplate, ramped up from ambient temperature to 65° C., the wafer is left at 65° C. for 30 minutes. It is then ramped up to 95° C., left at 95° C. for 100 minutes and ramped down to ambient temperature. The ramps up are set to 180° C./h and the ramp down to 120° C./h. Exposure is performed by direct laser writing photolithography (Heidelberg MLA150™, laser wavelength λ=375 nm), using a dose of 2000 mJ/cm² and light defocusing of +20. A post exposure bake is performed in the same way as prebake, the wafer is left at 65° C. for 5 minutes and 95° C. for 25 minutes. Patterns are developed using three baths of SU8 developer to avoid residues contamination of the microstructures developed. Development is achieved after 45 minutes in the first bath, 5 minutes in the second bath, 1 minute in the third bath and 30 seconds of rinsing in isopropanol. SU8 is finally baked on hotplate at 60° C. with a cap for 18 hours to complete crosslinking and release strain.

At the final step 290 of releasing, the sensor is released from the silicon wafer via the chemical etching in FeCl₃:H₂O 740 mMol of the copper sacrificial layer for a couple of hours at room temperature.

Thermal shocks have to be avoided during the process after deposition of the ZnO. From the sub step of deposition 264, all baking operations are performed by adding a ramp below 180° C./h or no baking when it is possible. For the sub step of forming 266 a mask on the active layer, the S1813 photoresist layer that acts as ZnO etching mask is spincoated the day before lithography. Prebake is replaced by an all-night solvent evaporation at ambient conditions. Hard bakes in step forming 280 the at least one cantilever and subsequent step(s) are performed with a 180° C./h ramping from ambient temperature to 150° C.

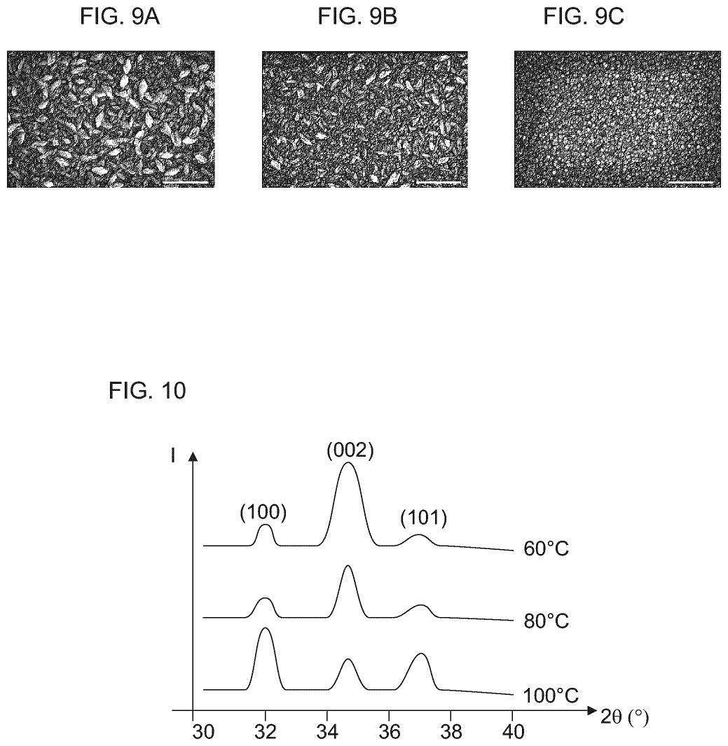

FIG. 9A, FIG. 9B, and FIG. 9C show scanning electron microscopy, SEM, top view images and associated grazing incident x-ray diffraction, GI-XRD, diffraction patterns)(ω=0.3° of ZnO thin films grown on substrates at a deposition temperature of (a) 100° C., (b) 80° C. and (c) 60° C. The obtained ZnO films were deposited with the same number of ALD loops (1000 loops). The scale bar corresponds to 300 nm.

FIGS. 9A-9C present the SEM top view images of ZnO thin films grown by Atomic Layer Deposition, ALD, on reference substrates with the associated grazing incident x-ray diffraction, GI-XRD, at a deposition temperature of: 100° C. in FIG. 9A, 80° C. in FIG. 9B and 60° C. in FIG. 9C. The deposited ZnO thin films are polycrystalline. At a temperature of 100° C., a different distribution of grain orientations can be observed, shared between the (100), (002) and (101) crystalline orientations.

FIG. 10 shows GI-XRD diffraction patterns of (ω=0.3° of ZnO films grown on top of 75 μm thick polymer substrates at 100° C., 80° C. and 60° C.

The deposited ZnO thin films are polycrystalline. At a temperature of 100° C., a different distribution of grain orientations can be observed, shared between the (100), (002) and (101) crystalline orientations. This is further confirmed by SEM top view images showing a distribution of wedge-like shaped crystallites parallel to the substrate and of fine columnar crystallites perpendicular to the substrate at this temperature. However, a transition is occurring as the deposition temperature is decreasing, with the (002) crystalline orientation substantially increasing at 80° C. and becoming dominant at 60° C. This is consistent with the appearance of fine columnar crystallites considerably increasing for decreasing deposition temperatures. This results in a significant change in the morphology of the ZnO thin films obtained at lower temperatures, where grains are predominantly oriented in the (002) direction perpendicular to the substrate, along the c-axis, which is especially important for piezoelectric applications.

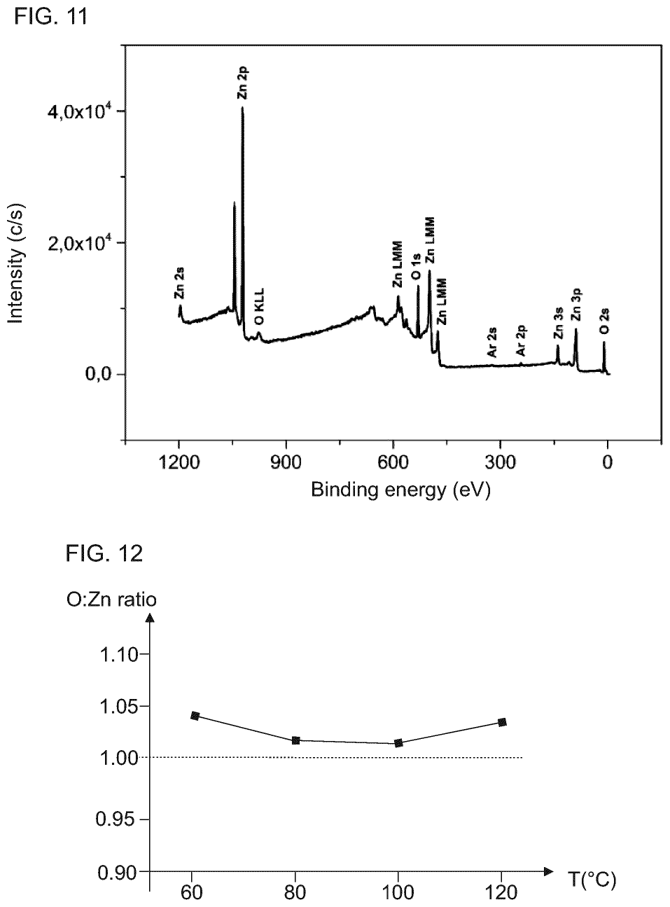

FIG. 11 shows the XPS survey spectrum of a ZnO thin film deposited by ALD at 80° C., obtained in the bulk of the thin film after Ar+ etching of the top surface.

The XPS survey spectrum corresponds to the in bulk of a ZnO thin film deposited by ALD at 80° C. Apart from the Ar 2s and Ar 2p peaks, related to Ar+ ions implantation due to the use of an Ar+ ion beam for depth profiling, every other peaks are related to Zn and O chemical elements, which confirms the high quality of the created ZnO thin films by ALD with not significant level of contaminants of others elements. The evolution of the O:Zn atomic ratio obtained by XPS depth profiling for ZnO thin films deposited in these conditions is displayed within FIG. 12.

FIG. 12 shows a graph illustrating the evolution of the O:Zn atomic ratio obtained by XPS depth profiling for the created ZnO thin films by ALD for different deposition temperatures. The O:Zn ratio is close to unity for every temperature studied between 60° C. and 120° C., which further confirms the above-mentioned statement. That ratio is expected to decrease when the temperature is increased to values higher than 150° C. The deposition of ZnO thin films by ALD at low temperatures is thus leading to a privileged stoichiometric growth, where the formation of ZnO defects, more precisely oxygen vacancies and zinc interstitials, is considerably reduced. It results in ZnO thin films presenting parameters well adapted for a Schottky behaviour, with high resistivity, low carrier concentration and adequate electron mobility.

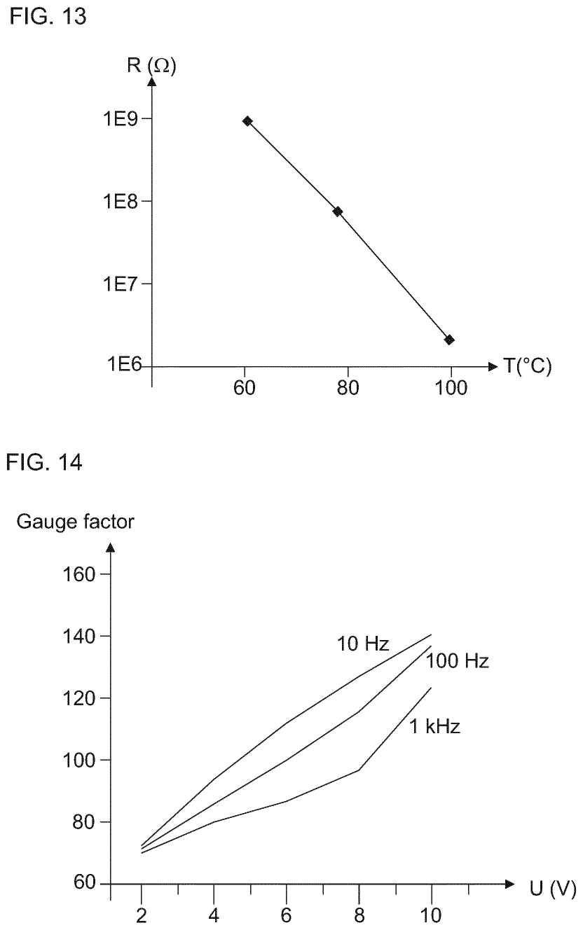

FIG. 13 is a graph illustrating the evolution of the resistance of ZnO thin films grown by ALD for different deposition temperatures on SU8 polymer surfaces for a sensor in accordance with the invention. The abscissa axis represents the deposition temperature, expressed in Celsius degrees. The ordinate axis represents the resistance of the zinc oxide layer. The resistance is expressed in Ohms, and is provided with a logarithmic scale. The resistance is measured by an electrometer system (Keithley 6517B™) with the same two tungsten tip probes spaced by 1 mm. The resistivity of the active layer, for instance comprising zinc oxide, reduces with the temperature.

FIG. 14 is a graph of the gauge factor evolution for different AC bias voltages at different frequencies for a sensor in accordance with the invention. The gauge factor traduces the conversion sensitivity (relative output current change over relative strain applied change) of the sensor. A clear trend can be identified as the gauge factor values are increasing while increasing the bias voltages, for every frequency studied. The highest gauge factor value has been evaluated at 150, for a bias voltage of 10 V promoting the non-linear behaviour of the sensors. Decreasing the ALD deposition temperature to 60° C. is leading to a substantial increase of the resistivity of the ZnO thin films, which is accompanied with a decrease of the sensor current values. At this lower temperature, the sensors are typically operating within tens to hundreds nanoAmperes range while the imposed bias voltage was increased up to 25 V. This allows for lowering the power consumption of the sensor until microwatt level. The same trends can be identified, as both the non-linear behaviour and the increase of the gauge factor are promoted at higher bias voltages.

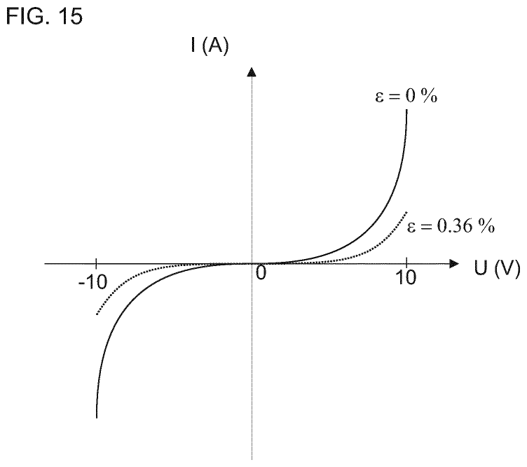

FIG. 15 is a graph illustrating the transducing output current to input bias response of the piezotronic strain microsensor arranged in a cantilever of a sensor in accordance with the invention. The ZnO thin film is deposited by ALD at 80° C. The bias voltage is AC modulated at 100 Hz to improve the signal to noise ratio.

The current response is amplified by the means of a transimpedance amplifier to get a usable voltage signal for the instrumentation chain. The current response is non-linear and shows a clear rectification behaviour conventional for diode junctions. The sensors responses are constantly symmetrical for both forward and reverse bias, which is typical from devices with symmetrical diode interfaces using the same metal electrodes in the case of back-to-back diodes. Due to the high resistivity of the sensors, related with low temperatures deposition, the bias voltage imposed had to be substantially increased to 10 volts to further promote the non-linear behaviour. An electrical power consumption lower than 50 μW is then reported. Piezotronic sensors thus appear as a promising candidate for low power consumption sensing technologies, compared to conventional piezoresistive and capacitive sensors operating in the milliWatt range.

The strain ε generated in the clamped area of the cantilevers has been calculated using the following equation:

ε=3/2·[{(t−ts)·(2L−Ls)}/{L³}]·d

With t being the cantilever thickness, ts is the sensor thickness, L the cantilever length, Ls the sensor length, and d the deflection imposed to the cantilever relatively to the contact point (at length L) of the force applied by a Z-axis piezostage (PI™ GmbH system) object during scanning probe and force spectroscopy operations.

The following equation has been used for the calculation of the gauge factor, based on the absolute value of the ratio of relative change in electrical current I, to the mechanical strain ε:

GF=|{ΔI/I0}·{1}/{ε}|

With I0 being the current at steady state for a given bias, and ΔI the change in current under a given strain ε for the same applied bias. This strain corresponds to the strain generated in the clamped end of the cantilevered sensor, calculated using the previous equation.

Based on these considerations, gauge factor values have been calculated by sweeping the bias voltage as well as the bias frequencies imposed to the sensors with a ZnO layer of 300 nm processed with an ALD deposition temperature of 80° C.

In all disclosed embodiments of the invention, it is preferred to obtain a Schottky contact responsive to mechanical strain by forming a junction comprising a high work function metal and a semiconductor thin film such as a ZnO layer, wherein the ZnO thin film exhibits a favoured (002) x-axis orientation. Obtaining a Schottky junction depends jointly on the high work function metal and on the control of the semiconducting properties of the ZnO thin film to get a relevant free carrier concentration Nd. Semiconducting properties depend on Nd (which should be comprised between 10¹⁶ and 10¹⁷ cm⁻³) and of the bandgap Eg˜3.3 eV at 300 K. In parallel, a high piezoelectric coefficient for ZnO are achieved by a favoured (002) c-axis orientation of the polycrystalline ZnO thin film on the surface. The obtained electrical parameters may be determined by non-linear fitting within the backward sweep of the experimental (I-V) characteristics. Fitting by the equation describing the conduction mechanism through the reverse biased Schottky junction in:

$${I}_{1} = A \cdot {A}^{⋆} \cdot {T}^{2} \cdot exp ( - \frac{q \cdot {ϕ}_{B 1}}{{k}_{B} \cdot T} ) \cdot exp ( \frac{q \cdot ( Δ {ϕ}_{B 1} + Δ {ϕ}_{B 1}^{′} )}{{k}_{B} \cdot T} ) \cdot [ 1 - exp \{ - \frac{q \cdot {V}_{1}}{{k}_{B} \cdot T} ) ]$$

It should be understood that the detailed description of specific preferred embodiments is given by way of illustration only, since various changes and modifications within the scope of the invention will be apparent to the person skilled in the art. The scope of protection is defined by the following set of claims.

1. A method for fabricating a sensor, said sensor comprising:
a polymer body and a strain gauge including at least one Schottky junction,
the Schottky junction comprising an active layer including a piezoelectric semiconductor material with a wurtzite crystalline structure, the Schottky junction further comprising at least one metal electrode electrically connected to the active layer;
the method comprising the following steps:
forming a polymer layer,
growing the at least one metal electrode on the polymer layer,
growing the active layer by atomic layer deposition on the polymer layer.

2. The method in accordance with claim 1, wherein the step of growing the active layer comprises using a deposition temperature ranging from: 20° C. to 150° C.

3. The method in accordance with claim 1, wherein the active layer comprises zinc oxide, the active layer and the at least one metal electrode defining a Schottky barrier.

4. The method in accordance with claim 3, wherein the step of growing the active layer comprises a molecular oxygen gas pulsing.

5. The method in accordance with claim 4, wherein the molecular oxygen gas pulsing comprises a time length ranging from 1 second to 5 seconds.

6. The method in accordance with claim 1, wherein the active layer comprises at least one of the following materials: gallium nitride, cadmium sulphide, indium nitride scandium doped aluminium nitride, and combinations thereof.

7. The method in accordance with claim 1, wherein the at least one metal electrode is comprised of platinum or platinum alloy.

8. The method in accordance with claim 1, wherein the at least one metal electrode is comprised of gold, silver, palladium, platinum alloy, gold alloy, silver alloy, or palladium alloy.

9. The method in accordance with claim 1, wherein the active layer defines a thickness ranging from 50 nanometres to 500 nanometres.

10. The method in accordance with claim 1, wherein the at least one metal electrode defines a thickness ranging from 100 nanometres to 200 nanometres.

11. The method in accordance with claim 1, wherein the at least one metal electrode comprises a work function of: at least 5.0 eV.

12. The method in accordance with claim 1, wherein at the step of growing the active layer, the active layer grows on the at least one metal electrode.

13. The method in accordance with claim 1, wherein the at least one metal electrode comprises two metal electrodes defining an interdigitated pattern.

14. The method in accordance with claim 1, wherein the active layer includes a wurtzite polycrystalline structure comprising a majority of grains exhibiting a (002) crystalline orientation, or a (001) crystalline orientation, or a (101) crystalline orientation.

15. The method in accordance with claim 14, wherein said (002) crystalline orientation, or said (001) crystalline orientation, or said (101) crystalline orientation is perpendicular to the polymer layer.

16. The method in accordance with claim 1, wherein the active layer comprises columnar (002) crystallite structures which are perpendicular to the polymer layer.

17. The method in accordance with claim 1, wherein the polymer layer is a transparent polymer layer, and wherein the polymer body is a transparent polymer body.

18. The method in accordance with claim 1, wherein the step of forming the polymer layer comprises using a SU8 epoxy-based photoresist.

19. The method in accordance with claim 1, wherein the step of forming the polymer layer comprises forming a polymer sensing peak, and at the step of growing the active layer, said active layer grows above the sensing peak.

20. The method in accordance with claim 1, wherein the process comprises a step of providing a sacrificial layer; at the step of forming the polymer layer, said polymer layer is formed on said sacrificial layer; the process further comprising a step of releasing the sensor from the sacrificial layer.

21. The method in accordance with claim 1, wherein the polymer body comprises at least one cantilever, the at least one Schottky junction being in the cantilever, wherein the process comprises a step of forming the at least one cantilever, which includes a first sub step of forming a lower polymer film with a thickness equal to an addition of a thickness of the active layer plus a thickness of the polymer layer; and a second sub step of forming an upper polymer film on the lower polymer film and on the active layer.

22. The method in accordance with claim 1, wherein at the step of growing the metal electrode, said metal electrode is grown by electron beam evaporation or by PVD sputtering.

23. The method in accordance with claim 1, wherein the step of growing the metal electrode comprises a sub step of photoresist patterning by laser lithography with a defocussing.

24. A sensor, comprising:
a polymer body including a strain gauge with at least one Schottky junction embedded in the polymer body, the Schottky junction including
an active layer including a piezoelectric semiconductor material, said piezoelectric semiconductor material comprising a wurtzite crystalline structure, and
at least one metal electrode electrically connected to the active layer, the active being obtained by atomic layer deposition, the polymer layer comprising a surface supporting the active layer and the at least one metal electrode, the sensor being obtained by the method in accordance with claim 1.

25. (canceled)
